(19) United States
(12) Patent Application Publication
(10) Pub. No.: US 2016/0344387 A1
(43) Pub. Date: Nov. 24, 2016

(54) EVALUATION METHOD FOR SENSOR SIGNALS

(71) Applicant: Huf Hülsbeck & Fürst GmbH & Co. KG, Velbert (DE)

(72) Inventors: Heinz-Paul STEUERMANN, Juechen (DE); Berthold SIEG, Bottrop (DE)

(21) Appl. No.: 15/112,140

(22) PCT Filed: Jan. 26, 2015
(86) PCT No.: PCT/EP2015/051433

§ 371 Date: Jul. 15, 2016

(30) Foreign Application Priority Data
Jan. 28, 2014 (DE) 10 2014 100 974.6

(51) Int. Cl. H03K 17/955; G06F 3/044; G01D 5/24

(52) U.S. Cl. CPC H03K 17/955; G01D 5/24; G06F 3/044; H03K 2217/960705

(57) ABSTRACT

A method for evaluating signal curves on sensor devices includes acquiring a temporal signal curve with a sensor device. Time intervals are formed from this signal curve, and at least one upper actual interval value and at least one lower actual interval value are calculated for each interval. The interval values for each interval are then compared with intervals of stored templates having comparison interval values assigned thereto, wherein it is determined whether the interval lies between the actual interval values inside the interval for the comparison interval values, and thus whether a valid actuation signal is present.

The invention relates to an evaluation method for sensor signals. In particular, the invention relates to a method for use with sensor devices that provide a signal that can change over time in relation to scanned procedures.

Temporally changing sensor signals are used for numerous applications. By way of example, such signals are acquired using proximity sensors, which sense the proximities of objects or people in an area. Temporally changing sensor signals are also acquired in the field of detecting operating gestures, likewise detected by proximity sensors or, by way of example, by touch-sensitive surfaces (capacitive displays).

The sequence of sensor values is analyzed using an evaluation logarithm, in order to enable an interpretation of the sensor values. By way of example, proximity sensors can be evaluated in order to detect on vehicles, the operating desire or opening desire for vehicle doors or vehicle hatches.

EP 2 616 287 A1 describes a method of this type, in which the capacitive sensor electrodes acquire a temporal sequence of sensor values, which are subsequently supplied to a neuronal network for evaluation. Using such evaluations, it should be ensured that the clear actuation desire or an actuation selection by a user is distinguished from an inadvertent actuation or some other change in the environment. On the other hand, due to the inherent imprecision of a human actuation, a certain tolerance must be taken into account in the recognition thereof.

In particular, threshold value comparisons, offset corrections, and testing of the change rates of signals are drawn on thereby for the evaluation.

The known methods occasionally place excessive demands on the computing capacities of the associated technical devices, e.g. processors. The evaluation should be executed with the simplest and most reliable computing processes. The invention therefore assumes the task of providing an improved method for pattern detection in sensor signals.

This objective is achieved by the method according to the invention, having the features of claim 1.

In accordance with the invention, a temporal signal curve is acquired at a sensor device. The sensor device can be any device that supplies temporally changing sensor signals that may accompany an event that is to be detected. By way of example, the sensor device can be formed by proximity sensors, optical sensors, ultrasound sensors, or touch sensors.

The temporally changing sensor signal is divided according to the invention into time intervals of the sensor curve. The sensor evaluation always occurs discretely with a technological implementation, thus in time intervals, wherein these time intervals can certainly be kept short. In accordance with the method according to the invention, one or more acquired sensor values are combined at time intervals along the time axis. The sensor signal has a value or a series of values in this interval.

An upper actual interval value (IU_{N}) and an associated lower actual interval value (IL_{N}) is then calculated for each interval, wherein N refers to a progressive index of the intervals. Thus, interval limits are derived from the sensor values in the examined intervals. These interval values determine a value range [IL_{N}, IU_{N}], which relates to the signal values in the examined interval.

The important thing is that, from a signal curve in which there is a signal value for each point in time, interval ranges [IL_{N}, IU_{N}] are formed having the size (or width) IU_{N}-IL_{N} in intervals. When examining a one-dimensional signal value, which can be illustrated by values along a time axis, the line formed by connecting the values is expanded in this manner to form a two-dimensional interval band having a width of IU_{N}-IL_{N}. A batch comparison is executed according to the invention, wherein, on one hand, a batch is generated from the current signal curve, and, on the other hand, a batch is stored as a template for comparison.

The method for computing the interval values from the measurement values can depend on the type of signal values. By way of example, discrete values can be added to or subtracted from the signal values in order to obtain the interval limits. A relationship, however, can be obtained for the interval limits from the signal values or their rate of change. In ranges having a higher signal dynamic, the spacing of the interval limits can be increased or decreased for example. Furthermore, the signal limits can also be calculated by first subjecting the present signal values to a pre-processing, e.g. formation of an average value, or other types of filtering.

The acquired signal curve also contains, according to the invention, a temporal interval range curve (IU_{N})_{N}, (IL_{N})_{N} after these steps have been executed. It is then provided, according to the invention, that this interval range is compared with a stored interval range curve (VIU_{N})_{N}, (VIL_{N})_{N}, a template. This template range represents a corresponding interval range from a pattern signal. The template range is formed, for example, in that the same calculation is used for the determination of the interval as that used on the measurement data. Other parameters, where applicable, can however also be used. A comparison signal, e.g. the signal from a sensor in the case of an actuation that is to be detected, then leads to a stored template, which is referenced for a comparison with the intervals for the actual measurement values. It is checked thereby whether the calculated interval range can be fit with its temporal curve inside a stored template range. As is shown below in the exemplary embodiments, this is not the same as the checking of whether the original signal curve or a filtered version of the original signal curve lies within the template. By expanding the measurement values into at least one further dimension, thus as for example the conversion of a signal line course into a signal band, and the comparison of this signal band to a template, an improved comparison analysis can be executed. This is because a comparison is carried out in more dimensions than contained in the original signal dimension. Even though the interval limits of the actual interval are derived from the original signal curve, the comparison operation according to the invention is superior to the comparison with the actual signal curve. By way of example, certain signal intervals may be more heavily weighted in this manner than others, or further objects, for example, may act on the signal band.

In a preferred embodiment of the invention, the temporal curve is broken down, such that each interval contains at least one signal measurement value.

It is fundamentally also possible to select the interval divisions such that they are smaller than the spacing between signal acquisitions, and then to interpolate or extrapolate the interval limits. Preferably, however, there is at least one signal value in each interval. In time periods in which there are periods without signals, e.g. due to disturbances, or a cycling of the sensor device that has been reduced in order to save energy, this then results in an expansion of the interval range.

In an advantageous embodiment of the invention, the derived intervals for each signal interval are selected such that the signal values in the regarded interval lie between the calculated interval values. The determined intervals then form a spaced apart, enveloping contour in relation to the signal values.

In a further development of the invention, it is furthermore taken into account that the signal values are dependent on temporally changing environmental conditions, e.g. changing usages and soiling of the sensor device, or the environmental conditions.

An at least piecewise, at least consistent function for a transformation is calculated in this embodiment from the signal curve or the signal curve and a template. By way of example, a piecewise affine function for a transformation, representing an offset correction, can be calculated. In the framework of this example, a piecewise, at least consistent function for an offset correction is calculated and subtracted from the temporal signal curve, in order to obtain the offset correction. The number of nodes for the piecewise affine function can be selected in relation to the expected signal curve. By way of example, it may be sufficient to use two or three nodes, in order to compensate for a linear offset modification over the course of the measurement. This may be necessary, for example, as a result of a decline or rise in the signal over the course of the measurement. A piecewise affine function, e. g. with a node at the start and end of the signal range corresponds to the correction of the signal curve having a linear function.

The transformed data, wherein the transformation in the specified example is a correction, are then subsequently used to calculate the interval values based on these adjusted data. In this manner, the stored comparison template can always find appropriate, transformed data, and an even more specific evaluation can be carried out.

Additionally or alternatively, it is also possible to subject the signal curve to a filtering, before the interval limits are calculated. The filtering can, for example, be composed of a smoothing, but other filterings can also be used, e.g. a filter for suppressing noise (e.g. a Wiener filter). In an alternative design, the filtering is also used, additionally or alternatively, on the interval limits.

In a further development of the invention, a norming of the batch generated from the measurement values can occur in the interval limits, prior to a comparison of the batches and intervals.

A norming relates thereby to the comparison of the width of the intervals generated from the measurement values with the width of the pattern template. This comparison can occur in intervals, or it can also be determined over the course of the entire measurement period. As a result of the norming, disruptive effects, in particular noise, which could be present in the current measurement, which, however, are not present during the generation of the template, are reduced. In a simple design, a factor is calculated, with which the interval limits are multiplied, wherein the factor is obtained by dividing the average width of the template by the average width of the interval widths calculated for the measurement values. The norming can be used in combination with a filtering and/or the offset correction.

The invention shall now be explained in greater detail based on the attached Figures.

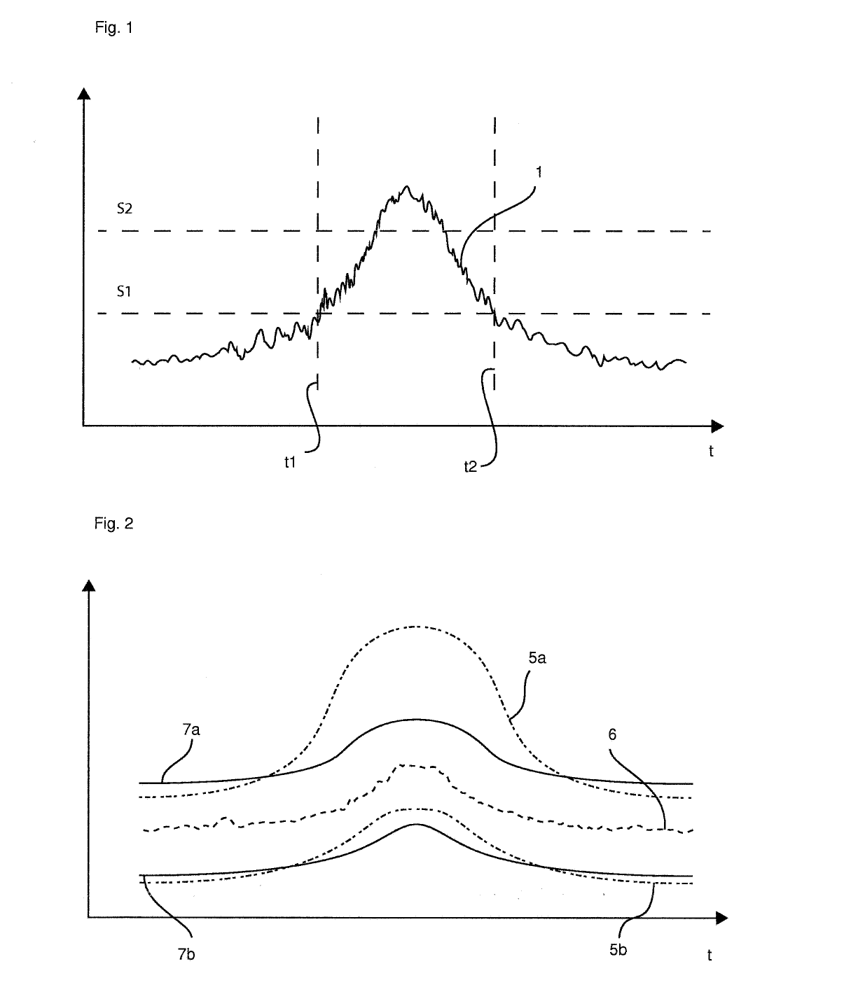

FIG. 1 shows, by way of example, a schematic signal curve for a sensor device;

FIG. 2 shows, in a schematic manner, a range comparison according to the invention, of an invalid signal curve;

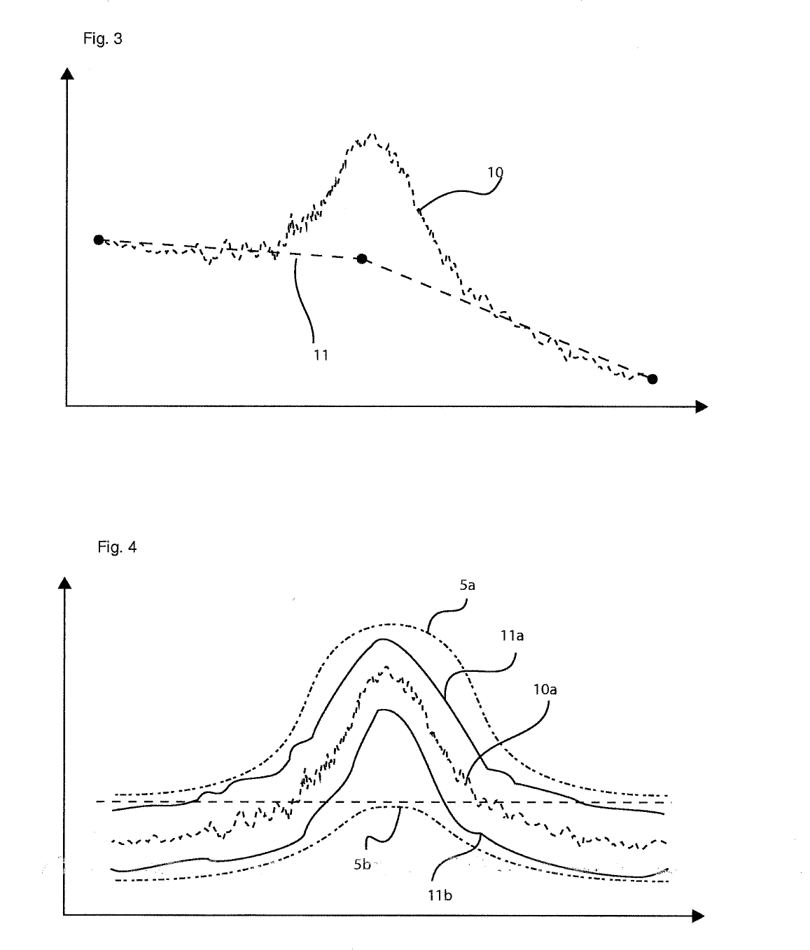

FIG. 3 shows, in a schematic manner, a signal curve intended for evaluation according to the invention;

FIG. 4 shows, in a schematic manner, the comparison range according to the invention, for a valid signal response.

A signal curve 1 is depicted in FIG. 1 in a schematic manner, which represents different signal strengths along a time axis. FIG. 1 thereby shows, by way of example, an evaluation of such a signal curve, in accordance with the prior art.

In order to examine the signal curve, threshold value comparisons are carried out with threshold values S1 and S2. Thus, the signal curve 1 is monitored, until the threshold value S1 is exceeded at time t1. Furthermore, it is monitored to see whether the signal value again falls below the threshold value S1, as is the case at time t2. The signal value must also have exceeded the threshold value S2 between these times. If the times t1 and t2 lie within a predefined interval, and thus fulfill all of the conditions, a positive and valid signal response is detected. This is an exemplary evaluation method in accordance with the prior art, in which the signal curve itself is referenced for evaluation with various comparison operations.

FIG. 2 shows the concept according to the invention, which carries out a type of template comparison of various areas. An evaluation template is defined by the upper interval limit 5a and the lower interval limit 5b. An area is delimited between these interval limits, which defines valid response ranges. An exemplary signal response 6 is likewise depicted, which does not, however, represent a valid signal response. The signal response 6 itself lies within the interval defined by the interval limits 5a and 5b. The signal curve 6 is not, however, referenced for the evaluation according to the invention. For signal curve 6 interval limits, which encompass an area are likewise calculated in accordance with calculation guidelines. The interval limits belonging to the signal curve 6 are the curves 7a and 7b. It can be seen that in intervals, the interval limits 7a and 7b are generated from the signal function 6 by combining numerous measurement values, and thus a smoothing function. It can likewise be seen that the area enclosed by the interval limits 7a and 7b generated from the signal curve 6 does not lie entirely within the template range, defined by 5a and 5b. Because the area derived from the signal curve 6 in this exemplary embodiment is not a subset of the template area, the signal response is regarded as invalid.

The important thing is that the evaluation takes place by means of a comparison, wherein the comparison range is higher than the dimension of the original signal by at least one order. As a rule, it would also be conceivable, that for two-dimensional data there is a match in the into a three-dimensional evaluation space.

FIG. 3 shows a signal curve, which should likewise be supplied with the same formula limits as in FIG. 2. It can be seen, however, that the signal curve declines over the course of the acquisition. This can be caused, for example, by a change in the environmental conditions or an unfavorable acquisition situation.

As is depicted in FIG. 3, a piecewise affine function 11 is calculated for the signal curve 10, having only three nodes in this example. This piecewise affine function 11 is drawn on for an offset correction of the signal curve 10, in order to form a signal curve 10a. Interval limits 11a and 11b are calculated piecewise, in turn, for this corrected signal curve 10a, as is shown in FIG. 4. The corrected signal curve 10a corrected by the piecewise affine function 11 likewise lies between the signal template limits 5a and 5b, as is the case with the signal curve 6 in FIG. 2. In this case, the area also lies within the template limits enclosed between the interval limits 11a and 11b, such that a valid actuation signal can be detected here.

The actual calculation of interval limits for a pattern signal curve is described below, based on an exemplary embodiment. In this example, a capacitive sensor is used for supplying the values. The capacitive sensor delivers signals changing over time due to a change in capacitance of the sensor caused by changes in the environment. The use of such capacitive sensors is known for electronic devices, in particular in vehicle locking systems as well. Capacitive sensor are used therein in “keyless entry” systems in door handles or in the hatch region of vehicles, in order to detect a proximity of a user. If a user brings his hand (in the case of a door handle) or his foot (in the case of a so-called kick sensor in the hatch region for opening the hatch) into the proximity of the capacitive sensor, the detected capacitance is changed, and an operating desire is derived from the temporal change in the signal. Numerous capacitive sensors for evaluating the signal responses of a capacitive sensor in the field of access systems are known in the prior art. By way of example, reference is also made to the method explained for FIG. 1.

According to the exemplary embodiment of the invention, a time sequence of sensor signals sₖ is detected with a capacitive sensor. The index k indicates the discrete values detected at intervals. The time sequence of the values is then s₀, s₁, . . . , sₖ, sₖ₊₁, . . .

Interval limits are derived from the measurement values in accordance with the following exemplary formulas:

LB((sₙ)ₙ, k; m, c₁, λ)=sₖ+(1−λ)·min (L((sₙ)ₙ; k, 0), c₁)+λ·min (L((sₙ)ₙ; k, m) , c₁)

UB((sₙ)ₙ,k; m, c₂, λ)=sₖ+(1−λ)·max (L((sₙ)ₙ; k, 0), c₂)+λ·max (L((sₙ)ₙ; k, m), c₂)

LB indicates the lower interval limit for a measurement value thereby.

UB indicates the upper interval limit for a measurement value thereby.

c₁, c₂, λ indicate smoothing parameters. λ can be selected as a power of 0.5 for example.

The expression L( . . . , . . . , . . . ) indicates a finite difference, determined from the curve of the measurement data.

Depending on how the parameters k, m and λ are selected, the interval limits depend not only on the observed measurement values sₖ, but rather, other, in particular preceding, measurement values are referenced, and a smoothing of the interval limits is carried out.

If λ=0 is selected in a simple consideration, then no smoothing occurs (the last addend falls out). If, for example, the parameters k, m=0, c₁=−0.5, c₂=0.5, λ=0 are selected, then the calculation of the interval limits is simplified to

LB=sₖ+min (sₖ−sₖ₋₁, −0.5)

UB=sₖ+max (sₖ−sₖ₋₁, 0.5)

The interval limits are calculated starting with current measurement values, wherein a negative portion of the curve of the measurement values, having a mollifier for forming the lower interval limit, is used, and the positive portion of the change in the curve, having a positive mollifier, is used in order to calculate the upper interval limit. The lower interval limit LB for the measurement value sₖ thus runs at least 0.5 units below sₖ, the upper interval limit UB runs at least 0.5 units above sₖ. In regions of steeper curves and greater dynamics, where sₖ−sₖ₋₁<−0.5, or sₖ−sₖ₋₁>0.5, these limits however have a greater spacing to the measurement value sₖ.

This calculation of the interval limits is carried out prior to the actual evaluation of measurement values for forming a template having a pattern curve of values. For this, a pattern actuation at a capacitive sensor for generating a data sequence is carried out, for example, and the interval limits for the pattern curve are stored. This template of interval limits can be created with other parameters than those used in the later evaluation. By way of example, in the present case, a parameter set having k, m=0, c₁=−0.7, c₂=0.7, λ=0 can be used for creating and storing the templates. The template is then expanded to a greater extent than the intervals in the later evaluations.

Instead of the preceding example, a more complex adjustment of the interval limits can occur, in that, e.g., the parameters m=15, c₁=−0.1, c₂=0.1, λ=0.75 are selected.

LB=sₖ+(0.25)min (L((sₙ)ₙ; k, 0) , −0.1)+0.75 min (L((sₙ)ₙ; k, 15) , −0.1)

UB=sₖ+(0.25)max (L((sₙ)ₙ; k, 0) , 0.1)+0.75 max (L((sₙ)ₙ; k, 15) , 0.1)

The selection of the parameters ensures, in this case, that further measurement values from the temporal curve are taken into account in the calculation of the interval limits. In this manner, a strong signal dynamic, or a previous strong noise as well, acts on the interval limits of following measurement values.

The selection of λ=0.75 results in a smoothing, such that the interval limits again adjust the temporal dynamic with a certain “buffering.”

The important thing is that templates are formed from pattern values according to the invention, wherein the templates follow a calculation formula, and define interval limits. In a measurement evaluation, interval limits are likewise determined for current measurement values, and it is checked whether the current interval limits are located within the interval limits of the templates. The manners of calculation for the creation of the templates and for the calculation of the interval limits can be identical, but structurally identical or similar calculation formulas having deviating parameter sets can also be used, such that the templates are calculated with different parameters than the interval limits for the current measurement values.

1. A method for evaluating signal curves at sensor devices, comprising the steps of:
detecting at least one temporal signal curve with a sensor device,
determining time intervals for the signal curve,
calculating at least one upper actual interval value and at least one lower actual interval value for each of the time intervals in accordance with a calculation formula, wherein the calculation formula takes at least the signals of the signal interval assigned thereto into account,
comparing the calculated upper actual interval values and lower actual interval values of each interval with intervals of stored comparison interval values assigned thereto, wherein it its determined whether the interval between the actual interval values lies within the interval of the comparison interval values for each interval.

2. The method according to claim 1, wherein each interval contains at least one signal measurement value.

3. The method according to claim 1, wherein the at least one upper actual interval value and the at least one lower actual interval value are calculated for each time interval of the signal values such that, in the respective interval, the signal values lie between the upper actual interval value and the lower actual interval value.

4. The method according to claim 1, wherein a piecewise affine function for an offset correction is calculated from the temporal signal curve, wherein the offset corrected signal data are used to calculate the actual interval values.

5. The method according to claim 1, wherein the temporal signal curve is first subjected to a filtering.

6. The method according to claim 1, wherein the temporal signal curve is first supplied after it has been normed, wherein the norming is calculated, depending on a comparison operation with the upper actual interval width and the stored comparison interval width.

7. The method according to claim 1, wherein the stored comparison interval values are calculated from a pattern signal curve, and are permanently stored.

8. The method according to claim 1, wherein the calculation formula for the lower actual interval value is:
IL((sₙ)ₙ, k; m, c₁, λ)=sₖ+(1−λ)·min (L((sₙ)ₙ; k, 0), c₁)+λ·min (L((sₙ)ₙ; k, m) , c₁), and
wherein the calculation formula for the upper actual interval value is:
IU((sₙ)ₙ,k; m, c₂, λ)=sₖ+(1−λ)·max (L((sₙ)ₙ; k, 0), c₂)+λ·max (L((sₙ)ₙ; k, c₂).

9. The method according to claim 8, wherein values of 0 to 1 are used for the parameter λ.

10. The method according to claim 5, wherein the filtering includes using a smoothing filter.

11. The method according to claim 9, wherein the value for the parameter λ is 0.5.
